(19) United States
(12) Patent Application Publication
(10) Pub. No.: US 2013/0077073 A1
(43) Pub. Date: Mar. 28, 2013

(54) METHODS TO CONTROL EUV EXPOSURE DOSE AND EUV LITHOGRAPHIC METHODS AND APPARATUS USING SUCH METHODS

(71) Applicants: Jan Bernard Plechelmus VAN SCHOOT, Eindhoven (NL); Hendrikus Robertus Marie VAN GREEVENBROEK, Eindhoven (NL); Vladimir Vitalevich IVANOV, Moscow (RU); Andrei Mikhailovich YAKUNIN, Mierlo (NL); Hermanus Johannes Maria KREUWEL, Schijndel (NL)

(72) Inventors: Jan Bernard Plechelmus VAN SCHOOT, Eindhoven (NL); Hendrikus Robertus Marie VAN GREEVENBROEK, Eindhoven (NL); Vladimir Vitalevich IVANOV, Moscow (RU); Andrei Mikhailovich YAKUNIN, Mierlo (NL); Hermanus Johannes Maria KREUWEL, Schijndel (NL)

(73) Assignee: ASML NETHERLANDS B. V., Veldhoven (NL)

(21) Appl. No.: 13/625,477

(22) Filed: Sep. 24, 2012

Related U.S. Application Data
(60) Provisional application No. 61/540,417, filed on Sep. 28, 2011.
(60) Provisional application No. 61/601,841, filed on Feb. 22, 2012.

(51) Int. Cl. G03F 7/20

(52) U.S. Cl. CPC G03F 7/70558
USPC 355/67

(57) ABSTRACT

EUV exposure dose in a lithographic apparatus is controlled pulse to pulse by varying a conversion efficiency with which a pulse of EUV radiation is generated from an excitation of a fuel material by a corresponding pulse of excitation laser radiation. Conversion efficiency can be varied in several different ways, by varying the proportion of a fuel material that intersects a laser beam, and/or by varying a quality of the interaction. Mechanisms to vary the conversion efficiency can be based on variation of a laser pulse timing, variation of pre-pulse energy, and/or variable displacement of a main laser beam in one or more directions. Steps to maintain symmetry of the generated EUV radiation can be included.

### CROSS-REFERENCE TO RELATED APPLICATIONS

This application claims the benefit of priority from U.S. Provisional Patent Application Nos. 61/540,417, filed Sep. 28, 2011, and 61/601,841, filed Feb. 22, 2012, the contents of both of which are incorporated herein by reference in their entireties.

### FIELD

The present invention relates to methods, systems and apparatus for controlling EUV exposure dose of a lithographic apparatus comprising an EUV radiation source.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{{NA}_{PS}} \qquad ( 1 )$$

where λ is the wavelength of the radiation used, NA_{PS} is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA_{PS}, or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources and discharge produced plasma sources.

EUV radiation may be produced using a plasma. A radiation system for producing EUV radiation may include a laser for exciting a fuel to provide the plasma, and a source collector apparatus for containing the plasma. The plasma may be created, for example, by directing a laser beam at a fuel, such as particles of a suitable material (e.g. tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam.

The source collector apparatus may include an enclosing structure or source chamber arranged to provide a vacuum environment to support the plasma. Such a radiation system is typically termed a laser produced plasma (LPP) source.

In projection lithography it is desirable to keep an effective exposure dose within tolerance during imaging of the pattern on the layer of resist provided on the substrate. The corresponding functionality of the lithographic apparatus is referred to, hereinafter, as Dose Control or simply as DC, which means to keep the emitted EUV radiation energy per second at a certain constant value. Generally, an exposure dose relates to the intensity of the light, the slit width and the speed at which a wafer is scanned. With a CO₂ laser LPP source, Dose Control is provided by controlling the RF pump energy driving the CO₂ laser, and consequently controlling the energy in each laser radiation pulse. The LPP source will typically produce fuel droplets and laser pulses at a rate of several thousand, or several tens of thousands, per second. Dose Control through the known mechanism of varying the RF pump energy is generally not fast enough to correct variations in the emitted radiation that may occur on a pulse-to-pulse timescale.

### SUMMARY

In order to optimize the number of dies that can be exposed per unit of time, it is desirable to provide alternative methods of Dose Control, in particular to provide Dose Control that is faster in response, and fast enough for example to correct pulse-to-pulse variations in EUV radiation dose.

According to an aspect of at least one embodiment of the present invention, there is provided a method of controlling EUV exposure dose of a lithographic apparatus having an EUV radiation source, comprising: controlling, pulse to pulse, a conversion efficiency with which a pulse of EUV radiation is generated from an excitation of a fuel material by a corresponding pulse of excitation laser radiation by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

The inventors have recognized that mechanisms to vary the conversion efficiency can be made much more responsive than mechanisms to vary the main pulse energy of the laser in an LPP source. Therefore varying the conversion efficiency provides a way to control the EUV radiation dose over much shorter timescales, and from pulse to pulse, if desired.

The target conversion efficiency may be set deliberately below the maximum achievable conversion efficiency. This gives the option to vary the conversion efficiency both up and down from a nominal value, enabling a simple feedback control to be implemented around a target value.

In some embodiments, a spatial overlap between the location of expanded fuel material and a cross-section of the laser radiation is varied to vary to conversion efficiency. This can be done for example but varying the timing of the a pulse of laser energy, while other methods are available.

In some embodiments, the method varies the timing and/or energy of a pre-pulse that is used to heat and expand the fuel material.

In some embodiments, the method of varying the conversion efficiency causes variation in the distribution of EUV radiation. These variations can be compensated in various ways, for example to steer the distribution back to a desired location, or to achieve a desired average distribution over several pulses.

According to an aspect of the invention, there is provided a device manufacturing method that includes controlling EUV exposure dose of a lithographic apparatus having an EUV radiation source of the type wherein pulses of EUV radiation are generated by excitation of expanded, heated portions of fuel material by corresponding pulses of excitation laser radiation by controlling, from pulse to pulse, a conversion efficiency with which said laser radiation is converted to said EUV radiation by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency; patterning said EUV radiation to form a patterned beam of radiation; and projecting the patterned beam of radiation onto a substrate.

According to an aspect of the invention, there is provided a lithographic apparatus that includes a source of EUV radiation; an illumination system configured to condition a radiation beam received from said EUV radiation source; a support constructed to support a patterning device, the patterning device being capable of imparting the radiation beam with a pattern in its cross-section to form a patterned radiation beam; a substrate table constructed to hold a substrate; a projection system configured to project the patterned radiation beam onto a target portion of the substrate; and a controller configured to control an exposure dose generated by said source of EUV radiation by controlling, from pulse to pulse, a conversion efficiency with which excitation laser radiation is converted to said EUV radiation by excitation of expanded, heated portions of fuel material by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

These and other aspects of the invention will be apparent to the skilled reader from a consideration of the examples described below, and the appended claims.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the present invention;

FIG. 2 is a more detailed schematic view of the embodiment of the lithographic apparatus of FIG. 1;

FIG. 3 depicts schematically a target material preconditioning position and a plasma formation position in the lithographic apparatus of FIG. 1 in a situation with maximum conversion efficiency CE; and

FIG. 4 depicts schematically a mismatch between droplet cloud and main pulse laser beam resulting in reduced CE;

FIG. 5 depicts schematically varying degrees of interaction between a main laser pulse and a droplet cloud traveling along a trajectory TR, when controlling CE in accordance with an embodiment of the present invention;

FIG. 6 is a schematic graph of CE against a mismatch distance 6 in the operation of the embodiment of FIG. 5;

FIGS. 7 (a), (b), and (c) show schematically an interaction area between main pulse and a fuel cloud at three different settings of CE, in the embodiment of FIG. 5;

FIGS. 8 (a), (b), and (c) show schematically an interaction area between two main laser pulses and respective fuel clouds at three different settings of CE, in an embodiment of the invention;

FIGS. 9 (a) and (b) show schematically an interaction area between the cloud and a main laser pulse at three different settings of CE, in an embodiment of the invention;

FIG. 10 depicts schematically the scanning direction of an exposure slit on a wafer (substrate) in operation of the lithographic apparatus;

FIG. 11 depicts schematically an embodiment of the invention in which CE is controlled by varying a pre-pulse energy;

FIG. 12 is a schematic graph of CE against the size of a fuel cloud in the operation of the embodiment of FIG. 11;

FIG. 13 depicts schematically an embodiment of the invention in which CE is controlled by varying a pre-pulse energy; and

FIG. 14 is a schematic graph of CE against the size of a fuel cloud in the operation of the embodiment of FIG. 13.

### DETAILED DESCRIPTION

FIG. 1 schematically depicts a lithographic apparatus 100 including a source collector apparatus 42 according to an embodiment of the invention. The apparatus 100 comprises an illumination system (illuminator) IL configured to condition a radiation beam B (e.g. EUV radiation), a support structure (e.g. a mask table) MT constructed to support a patterning device (e.g. a mask or a reticle) MA and connected to a first positioner PM configured to accurately position the patterning device, a substrate table (e.g. a wafer table) WT constructed to hold a substrate (e.g. a resist coated wafer) W and connected to a second positioner PW configured to accurately position the substrate, and a projection system (e.g. a reflective projection system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g. employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source collector apparatus 42. Methods to produce EUV light include, but are not limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector apparatus 42 may be part of an EUV radiation system including a laser, not shown in FIG. 1, for providing the laser beam exciting the fuel. The resulting plasma emits output radiation, e.g., EUV radiation, which is collected using a radiation collector, disposed in the source collector apparatus. The laser and the source collector apparatus may be separate entities, for example when a CO₂ laser is used to provide the laser beam for fuel excitation.

In such cases, the laser is not considered to form part of the lithographic apparatus and the radiation beam is passed from the laser to the source collector apparatus with the aid of a beam delivery system comprising, for example, suitable directing mirrors and/or a beam expander. In other cases the source may be an integral part of the source collector apparatus, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using mask alignment marks M1, M2 and substrate alignment marks P1, P2.

The depicted apparatus could be used in at least one of the following modes:

1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

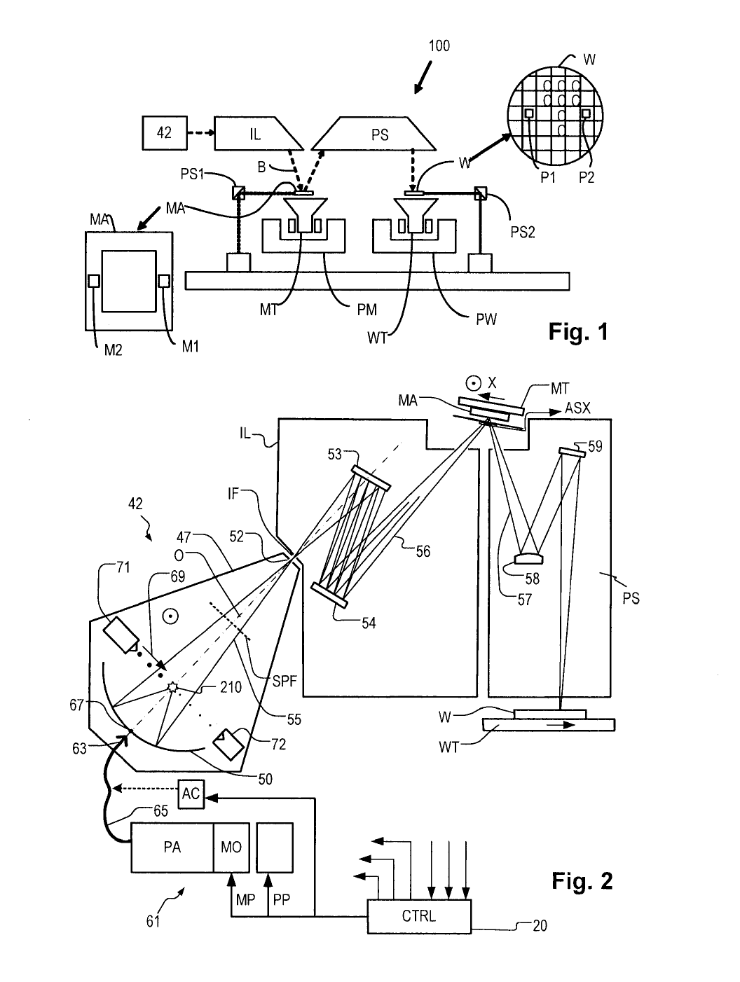

FIG. 2 shows the apparatus 100 in more detail, including the source collector apparatus 42, the illumination system IL, and the projection system PS. The source collector apparatus 42 is constructed and arranged such that a vacuum environment can be maintained in an enclosing structure 47 of the source collector apparatus 42. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, optical excitation using CO₂ laser light causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

Source collector apparatus 42 comprises a source chamber 47, in this embodiment not only substantially enclosing a source of EUV radiation, but also a collector mirror 50 which, in the embodiment of FIG. 2, is a normal-incidence collector, for instance a multi-layer mirror.

As part of an LPP EUV radiation source, a laser system 61 (described in more detail below) is constructed and arranged to provide a laser beam 63 which is delivered by a beam delivery system 65 through an aperture 67 provided in the collector mirror 50. Also, the source collector apparatus includes a target material 69, such as Sn or Xe, which is supplied by target material supply 71. The beam delivery system 65, in this embodiment, is arranged to establish a beam path coincident with a predetermined plasma formation position 73. The plasma formation position may be arranged to be substantially coincident with a first focal point of collector mirror 50.

In operation, the target material 69, which may also be referred to as fuel, is supplied by the target material supply 71 in the form of droplets. When such a droplet of the target material 69 reaches the predetermined plasma formation position 73, the laser beam 63 impinges on the droplet and an EUV-radiation emitting plasma 210 forms inside the source chamber 47. In the case of a pulsed laser, this involves timing the pulse of laser radiation to coincide with the passage of the droplet through the position 73. In the embodiment of FIG. 2, EUV radiation emitted by the plasma at position 73 is focused by the normal-incidence collector mirror 50 and, optionally via a spectral purity filter SPF, onto a second focal point of the collector mirror 50.

The beam of radiation emanating from the source chamber 47 traverses the illumination system IL via so-called normal incidence reflectors 53, 54, as indicated in FIG. 2 by the radiation beam 56. The normal incidence reflectors direct the beam 56 onto a patterning device (e.g. reticle or mask) positioned on a support (e.g. reticle or mask table) MT. A patterned beam 57 is formed, which is imaged by projection system PS via reflective elements 58, 59 onto a substrate carried by wafer stage or substrate table WT. More elements than shown may generally be present in illumination system IL and in the projection system PS. For example in the projection system PS there may be one, two, three, four or even more reflective elements present besides the two elements 58 and 59 shown in FIG. 2.

As schematically depicted in FIG. 2, a transmissive optical spectral purity filter SPF may be applied. Optical filters transmissive for EUV and less transmissive for or even substantially absorbing UV radiation or Infra Red radiation are known in the art and include gratings or transmissive filters.

Referring to FIG. 2, the source collector apparatus 42 is arranged to deposit laser beam 63 into a fuel, such as xenon (Xe), tin (Sn) or lithium (Li), creating the highly ionized plasma 210 with electron temperatures of several 10's of eV. Higher energy EUV radiation may be generated with other fuel materials, for example Tb and Gd. The energetic radiation generated during de-excitation and recombination of these ions is emitted from the plasma, collected by a near-normal incidence collector 50 and focused on the aperture 52. The plasma 210 and the aperture 52 are located at first and second focal points of collector 50, respectively.

To deliver the fuel, which for example is liquid tin, a droplet generator or target material supply 71 is arranged within the source chamber 47, to fire a stream of droplets towards the desired location 73 of plasma 210. In operation, laser beam 63 may be delivered in a synchronism with the operation of target material supply 71, to deliver impulses of radiation to turn each fuel droplet into a plasma 210. The frequency of delivery of droplets may be several kilohertz, or even several tens or hundreds of kilohertz. In practice, laser beam 63 may be delivered by a laser system 61 in at least two pulses: a pre pulse PP with limited energy is delivered to the droplet before it reaches the plasma location 73, in order to vaporize the fuel material into a small cloud, and then a main pulse MP of laser energy is delivered to the cloud at the desired location 73, to generate the plasma 210. In a typical example, the diameter of the plasma 210 is about 200-300 μM. A trap 72 is provided on the opposite side of the enclosing structure 47, to capture fuel that is not, for whatever reason, turned into plasma.

Referring to laser system 61 in more detail, the laser in the illustrated example is of the MOPA (Master Oscillator Power Amplifier) type. The laser system 61 includes a “master” laser or “seed” laser, labeled MO in the diagram, followed by a power amplifier system PA, for firing a main pulse of laser energy towards an expanded droplet cloud, and a pre pulse laser for firing a pre pulse of laser energy towards a droplet. A beam delivery system 65 is provided to deliver the laser energy 63 into the source chamber 47. In practice, the pre-pulse element of the laser energy may be delivered by a separate laser. Laser system 61, target material supply 71 and other components can be controlled by a control module 20. Control module 20 may perform many control functions, and have many sensor inputs and control outputs for various elements of the system. Sensors may be located in and around the elements of source collector apparatus 42, and optionally elsewhere in the lithographic apparatus. In one embodiment of the present invention, the main pulse and the pre pulse are derived from a same laser. In another embodiment of the present invention, the main pulse and the pre-pulse are derived from different lasers which are independent from each other.

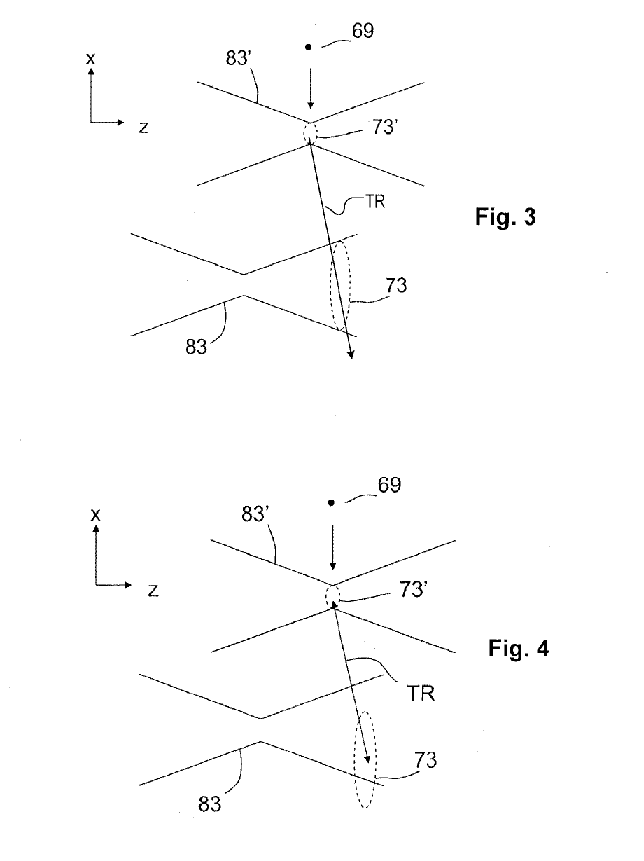

As the skilled reader will know, reference axes X, Y and Z may be defined for measuring and describing the geometry and behavior of the apparatus, its various components, and the radiation beams 55, 56, 57. At each part of the apparatus, a local reference frame of X, Y and Z axes may be defined. The Z axis of a local reference system may, for example, coincide with the direction of optical axis O at a given point in the system, or may be normal to the plane of a patterning device (reticle) MA and normal to the plane of substrate W. In the source collector apparatus 42, the X axis coincides substantially with the direction of fuel stream 69 described below, while the Y axis is orthogonal to the direction of fuel stream 69, pointing out of the page as indicated in FIG. 3. On the other hand, in the vicinity of the support structure MT that holds the reticle MA, the X axis is generally transverse to a scanning direction aligned with the Y axis. For convenience, in this area of the schematic diagram FIG. 2, the X axis points out of the page, again as marked. These designations are conventional in the art and will be adopted herein for convenience. In principle, any reference frame can be chosen to describe the apparatus and its behavior.

Many measures can be applied in the controller 20. Such measures include monitoring a position of an image of the EUV-radiation emitting plasma 210; this image is also referred to as the virtual source point or as the intermediate focus point IF, and is positioned at or near the second focal point of the collector mirror 50. The measures include in particular to check that the intermediate focus point IF is centered with respect to the aperture 52, at the exit from the source chamber 47. In systems based on LPP sources, control of alignment is generally achieved by controlling the location of the plasma 210, rather than by moving the collector optic 50. The collector optic, the exit aperture 52 and the illuminator IL are aligned accurately during a set-up process, so that aperture 52 is located at the second focal point of collector optic. However, the exact location of the virtual source point IF formed by the EUV radiation at the exit of the source optics is dependent on the exact location of the plasma 210, relative to the first focal point of the collector optic. To fix this location accurately enough to maintain sufficient alignment generally requires active monitoring and control.

For this purpose, controller 20 in this example may control the location of the plasma 210 (the source of the EUV radiation), by controlling the injection of the fuel, and also for example the timing of energizing pulses from laser system 61. In a typical example, energizing pulses of laser radiation 63 are delivered at a rate of 50 kHz (period 20 μs), and in bursts lasting anything from, for example, 20 ms to 20 seconds. The duration of each main laser pulse may be around 1 μs, while the resulting EUV radiation pulse may last around 2 μs. By appropriate control, it can be maintained that the EUV radiation beam 55 is focused by collector optic 50 precisely on, and centered with respect to the aperture 52. If this is not achieved, all or part of the beam will impinge upon surrounding material of the enclosing structure. In that case, a heat dissipation mechanism can be used to absorb the EUV radiation incident on the enclosing structure.

In accordance with current practice, control module 20 is supplied with monitoring data from one or more arrays of sensors (not shown) which provide a first feedback path for information as to the location of the plasma. The sensors may be of various types, for example as described in United States Patent Application Publication No. 2005/0274897A1. The sensors may be located at more than one position along the radiation beam path. In an embodiment, the sensors may, for example, be located around and/or behind the field mirror device 53. The sensor signals just described can be used for control of the optical systems of the illuminator IL and projection system PS. They can also be used, via feedback path, to assist the control module 20 of the source collector apparatus 42 to adjust the intensity and position of the EUV plasma source 73. The sensor signals can be processed for example to determine the observed location of the virtual source IF, and this is extrapolated to determine, indirectly, the location of the EUV source. If the virtual source location drifts, as indicated by the sensor signals, corrections can be applied by control module 20 to re-center the beam in the aperture 52. Also, the beam delivery system 65 can include a mirror. A main pulse of laser light fired by laser system 61 may be incident on the mirror and directed by the mirror towards a droplet of the target material 69. Sensors can be placed close to such a mirror for monitoring a tilting angle of the mirror, and the relevant monitoring data relating to the tilting angle are fed back to control module 20. Control module 20 can use the relevant monitoring data from the sensors to trigger the actuator AC to adjust the tilting angle of the mirror.

Rather than rely entirely on the signals from the illuminator sensors, additional sensors and feedback paths will generally be provided in the source collector apparatus 42 itself, to provide for more rapid, direct and/or self-contained control of the radiation source. Such sensors may include one or more cameras, for example, monitoring the location of the plasma. By this combination of means, the location of beam 55 can be maintained in, the aperture 52, and damage to the equipment is avoided, and efficient use of the radiation is maintained.

In addition to monitoring the position of the plasma 210, sensors at the illumination system and sensors at the reticle level monitor the intensity of the EUV radiation, and provide feedback to control module 20. Conventionally, intensity is controlled for example by adjusting the energy of the laser pulses.

Radiation passed by collector optic 50 passes in this example through a transmissive filter spectral purity filter SPF, located near the intermediate focus point IF.

An LPP EUV light source comprising an arrangement to irradiate a target material in order with a pre-pulse of laser light and a main pulse of laser light is described in United States Patent Application Publication No. 2011/0013166. The pre-pulse of laser light serves to heat and expand the target material before it reaches a position where it is hit by the main pulse of laser light. In such an arrangement an improved Conversion Efficiency can be obtained. A heated and expanded droplet of target material is also referred to, hereinafter, as a droplet-cloud or cloud.

FIG. 3 schematically illustrates an arrangement where a droplet of target material 69 reaches a predetermined preconditioning position 73′ that is located upstream in the trajectory of the droplet with respect to a further, predetermined plasma formation position 73. In use, droplets of the target material 69, for example Sn or Xe, are moved along a trajectory, in FIG. 2 by dropping or firing the droplets from a position above the predetermined preconditioning position 73′ and the predetermined plasma formation position 73. When such a droplet reaches the predetermined preconditioning position 73′, a laser light beam path 83′ of a pre pulse is established along which at least part of the optical gain medium is positioned. The optical gain medium produces a further amplified photon beam along a further beam path 83 of a main pulse to interact with the pre-conditioned droplet of the target material 69 at predetermined plasma formation position 73. As is known, a beam of laser radiation will have a finite cross-sectional area that tapers to a location known as the ‘beam waist’ and then widens again. The beam waist of laser beam 83 is illustrated just in advance of the plasma position 73, although the tapering is greatly exaggerated in these diagrams. Thus, the position of the beam waist of laser beam 83 relative to the position of the predetermined plasma formation position 73 is arranged such that a main laser pulse first traverses the beam waist of laser beam 83 and next traverses the predetermined plasma formation position 73.

The interaction at the predetermined preconditioning position 73′ causes the droplet of the target material 69 to heat and expand before it reaches the predetermined plasma formation position 73. This may be advantageous to conversion efficiency when the EUV radiation is created from the droplet. The EUV radiation system with the preconditioned droplet or cloud is thus expected to provide more EUV radiation, thereby improving throughput of any lithographic apparatus in which it is employed.

With increasing conversion efficiency, the exposure time suitable for patterning a die by imaging of the pattern on the layer of resist provided on the substrate, the time to provide the appropriate effective exposure dose becomes shorter. It is therefore desirable to provide a correspondingly sufficiently fast Dose Control.

In an embodiment of the present invention, a pulsed laser of the LPP source is operated at 40-400 kHz. In this embodiment, there is provided a method to control EUV exposure dose by controlling, on a pulse-to-pulse basis (thus, for a single laser pulse or for a few pulses) the conversion efficiency with which a pulse of EUV radiation is generated from excitation of an expanded, heated portion of Sn fuel by a pulse of excitation laser radiation. It is appreciated that a prior art method of providing Dose Control consists of changing and/or controlling the RF energy driving the CO₂ laser. Changing the RF energy of the CO₂ laser is a slow mechanism, where it takes at least 100 μs from increasing the RF energy until the pulse power of the CO₂ laser is increased. This prior art DC has a time constant of, for example 100 μs, whereas a time constant one or more orders of magnitude smaller is desirable for sufficiently fast DC. Further, it is appreciated that with prior art DC a changing the power of the seed lasers is not effective, since the last cavity of the CO₂ laser is typically completely depleted, so changing the seed power is not translated into a change of output power.

According to an aspect of the embodiment, a timing of the pre-pulse delivery with respect to the corresponding main pulse delivery is controlled and/or adjusted, thereby changing the conversion efficiency CE of the EUV generation process. It is appreciated that this can be done without changing the main pulse energy, although the main pulse energy can be adjusted, if desired, over a longer timescale. An effect of changing the relative timing of the pre-pulse and the main pulse is schematically shown by comparison of FIGS. 3 and 4. For example, the trajectory of the droplet cloud illustrated by the arrow TR in FIGS. 3 and 4 is unaffected by the timing of the main pulse. However, the portion of the droplet-cloud hit by the main pulse is affected by this timing. FIG. 4 shows the effect of a delay of the main pulse with respect to the pre-pulse. A the time when the pulse arrives, a portion of the fuel material has passed outside the beam path 83, and will not be converted to EUV-emitting plasma. Thus the conversion efficiency in the situation as depicted in FIG. 4 is lower than the conversion efficiency in the situation as depicted in FIG. 3. Similarly, if the timing of the main pulse were to be advanced, a portion of the fuel material would not yet have entered the beam path, and the conversion efficiency would again be reduced compared with the maximum achievable.

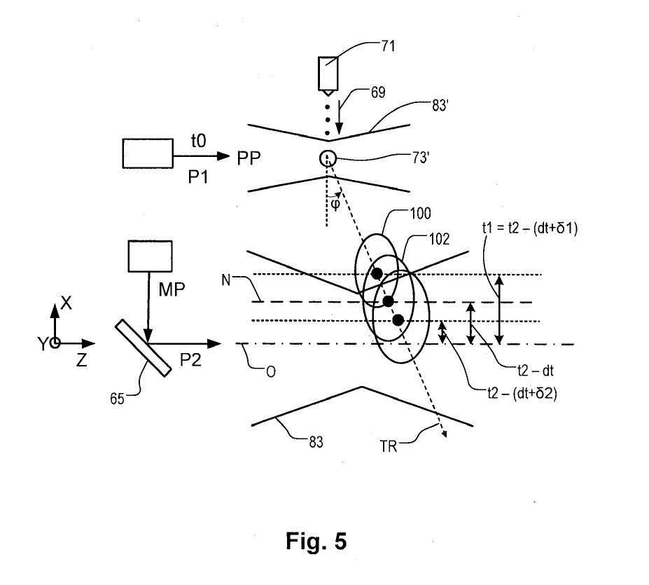

FIG. 5 depicts schematically a detailed view of degrees of alignment between a droplet cloud along a trajectory TR and a main laser pulse. According to FIG. 5, after a stream of droplets of target material 69 is generated from target material supply 71, a pre-pulse of laser light forming laser beam 83′ can be fired by the pre pulse laser at times t0, so as to turn each fuel droplet of respective droplets into a fuel cloud, the fuel cloud then traveling along the trajectory TR. The trajectory TR deviates from the trajectory of the original droplet by an angle φ that depends on the pre pulse energy P1. It may be defined that the time of firing a pre-pulse or a main pulse is a value relative to the time of generating a droplet by target material supply 71. The size of a cloud may further expand as it travels through positions 100, 102, 104 along the trajectory TR. Conventionally, when the cloud travels along the trajectory to traverse the optical axis O, it is desired that a main pulse 83 is fired at time t2 so that the cloud can fully match with main pulse beam path 83. However, in an embodiment of the present invention the time of delivering the main pulse to the cloud is deliberately offset by an amount dt by firing it at a time t2 minus an offset in accordance with

t2−(offset)=t2−dt (2)

In equation (2), dt is a positive amount of time, hence the offset by time dt amounts to firing the main pulse laser earlier than at time t2. As a result, instead of a full match between main beam path 83 and the cloud, there is a partial alignment area between beam path 83 and the cloud at a designated nominal position 102. As the EUV radiation energy is generated from the part of the laser energy of the main pulse 83 interacting with the cloud, an exposure dose control can be achieved by controlling the partial alignment, and hence the degree of interaction between the beam path 83 and the target material 69. Compared with a full match between main pulse 83 and the cloud, it is possible to control the degree of interaction between main pulse 83 and the cloud, so as to control the amount of EUV radiation generated from the excitation of fuel in the cloud by main pulse 83. Thus, a fast exposure dose control becomes possible by varying the degree of interaction between main pulse 83 and a droplet of the target material 69. This is done by applying to the firing time t2, on top of the offset dt, additional offsets 6 from pulse to pulse. For example an additional offset δ=δ1 (δ1 is a positive amount of time) leads to a reduced interaction, and an additional offset δ=δ2 (δ2 is a negative amount of time) leads to an increased interaction. It will be seen that, by offsetting the timing t2 with an amount dt to a nominal timing t2−dt, where conversion efficiency is below the maximum achievable, it is possible to vary the conversion efficiency up or down from the nominal value, greatly facilitating the use of this phenomenon in a feedback control loop. As a velocity component of the cloud along the X direction is not affected by the pre-pulse energy P1, a distance d from a center of the fuel cloud to the optical axis O in the X direction is determined solely by the timing of firing main pulse 83. In FIG. 5 the double arrows indicate the distances d for different timings of the main pulse; each double arrow is referred to by the associated main pulse timing. As illustrated in FIG. 5, the partial alignment of the fuel cloud with the main pulse laser beam, and consequently, the degree of interaction between the cloud and main pulse 83 can be varied by controlling the timing of firing main pulse 83 towards the cloud.

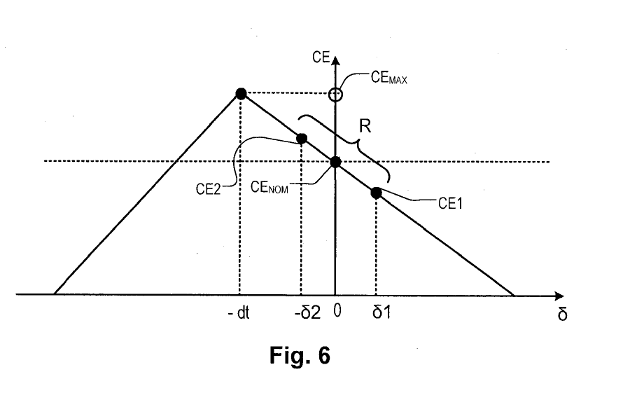

FIG. 6 is a graph showing the effect on conversion efficiency CE of the main-pulse timing adjustment 6 (an additional offset) which affects the X axis distance of the cloud relative to the nominal position 102. Referring to FIG. 6, when 6 is zero, the value of CE is the nominal value CE_{NOM}. The CE value is at a maximum CE_{MAX} when the timing adjustment δ is −dt, which means that the time of firing main pulse 83 as shown in FIG. 5 is delayed until the cloud reaches the optical axis O to have a full match with the laser beam. It can be seen that the graph of CE in FIG. 6 provides an operating region R in which CE has a roughly linear relationship with the timing adjustment 6. In practice, of course linear relationship will be only approximate, and the graph illustrated is purely schematic. To have a CE value lower than CE_{NOM}, adjustment 6 shall be greater than zero or less than −2dt. This means that the time of firing main pulse 83 shall be either at t1=t2−(dt+δ1) as illustrated, or at t3, with t3>t2−(dt+δ2) and δ2<−2dt (not shown in FIG. 5).

According to the embodiment just described, it can be seen that a method of controlling the conversion efficiency comprises setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

The conversion efficiency is varied by varying a mutual cross-section (degree of overlap) between a cross-sectional area of the main pulse laser radiation beam and a cross-sectional area of the expanded cloud of fuel material. The mutual cross-section can be varied at least in part by advancing or retarding the timing of each pulse of laser radiation while said fuel material traverses said laser radiation cross section, such that a greater or lesser proportion of said material is within the laser radiation cross section at the time of the pulse.

Based on EUV pulse energy for one or more EUV pulses contributing to an exposure of a die, a new EUV energy set point for a next pulse can be derived and controlled up or down by varying the timing adjustment 6 of the next main pulse or group of pulses. By feedback with a longer time constant, any bias observed in the timing adjustments can be eliminated by adjusting the laser energy through conventional feedback control.

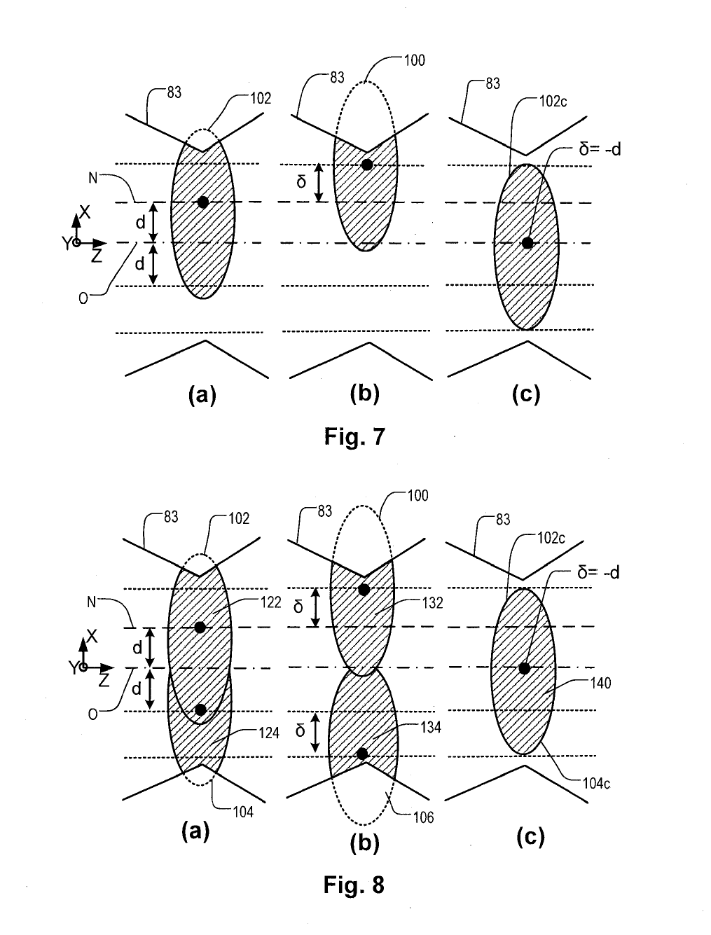

FIGS. 7(a), (b), (c) show schematically a more detailed X-Z plane cross sectional view of the degree of interaction between main pulse laser beam 83 and the fuel cloud at different positions 100, 102, 102c along the trajectory TR, as shown in FIG. 5 for a situation where δ1=δ2=dt. FIG. 7(a) shows the situation where the time of firing a main pulse is at t2-dt whereby the corresponding distance in X axis between the fuel cloud and the optical axis O is d. FIG. 7(b) shows the time of firing main pulse is at t1=t2−2dt so that the distance in X axis between the cloud and the optical axis O is greater than d. FIG. 7(c) shows the time of firing main pulse 83 is at t2 so that there is a full match between the cloud and the main pulse 83. Conventionally cloud position 102c would be chosen as the target or nominal position of the cloud, but in that case it would not be possible to adjust the exposure dose upwards by simply varying the degree of interaction between main pulse 83 and the cloud; instead only a downwards adjustment of exposure dose would be possible. If the nominal position of the cloud is set as position 102 (FIG. 7(a)), the degree of interaction between the cloud and the main pulse 83 can be varied down (FIG. 7 (b)) or up (FIG. 7(c)) on a pulse-to-pulse basis, thereby achieving a fast dose control.

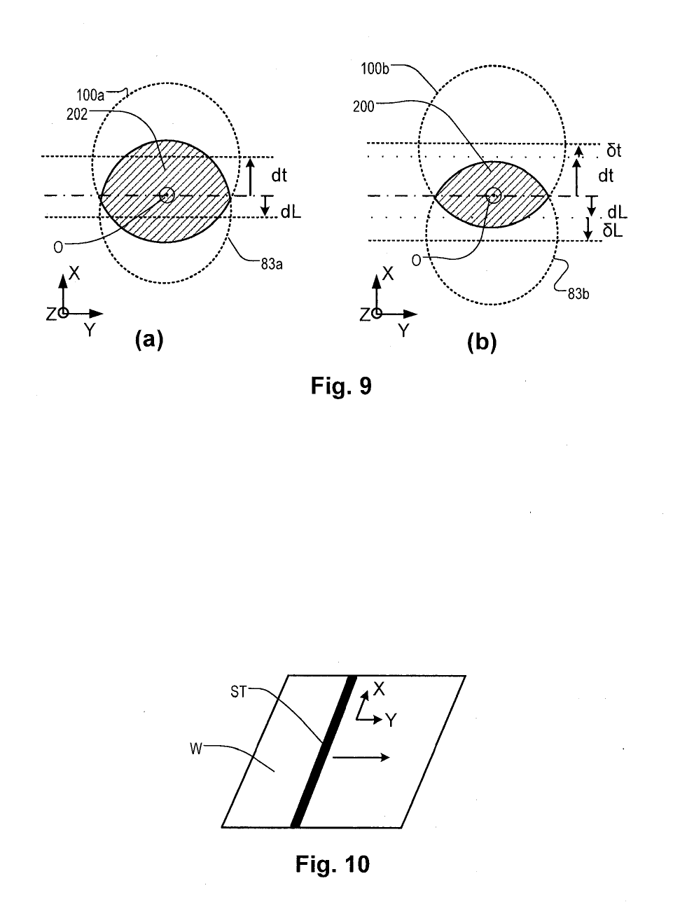

An undesirable side-effect of the offset of the nominal position 102 illustrated in FIG. 7 is an asymmetry of the location of the portion of the fuel cloud that interacts with the main pulse laser radiation. Consequently the generated plasma that is the source of EUV radiation is offset by a varying amount from the optical axis O. Such an offset introduces an asymmetry and potentially other changes in the intensity distribution of the EUV radiation entering the illumination system IL, which can have a detrimental effect on the quality of imaging in the projection system PS. Further embodiments and modification of the embodiments will now be described, which eliminate or average out this asymmetry. A first solution to this is to offset a next main pulse in an ‘opposite’ direction, as further explained below by reference to FIG. 8. Another solution is to adjust both the cloud and the laser beam path main pulse as further explained below by reference to FIG. 9.

FIG. 8 shows schematically a more detailed X-Z plane cross sectional view of the degree of interaction between two fuel clouds and two main pulses of laser radiation in a first modification of the above embodiment. FIG. 8(a) shows that a first main pulse is fired at time t2−dt relative to the pre-pulse timing, the same as in FIG. 7. However a second main pulse is fired at t2+dt, that is with an offset opposite to the offset used in the first pulse. The interaction area between the first main pulse and its fuel cloud is shaded as 122 and the interaction area between the second main pulse and its fuel cloud is shaded as 124. An effect of the having offsets −dt and +dt for firing the first main pulse and the second main pulse is to offset the interaction areas, and consequently the generated plasma, by equal and opposite amounts in the X direction. Consequently, compared with FIG. 7(a), the intensity distribution of the EUV radiation when averaged over the two pulses is more symmetrical around the optical axis O. This average symmetry can be maintained while varying the timing adjustment to control the conversion efficiency up and down. FIG. 8(b) shows a symmetrical version of the situation shown in FIG. 7(b), in which reduced interaction areas are shown as 132 and 134 respectively. FIG. 8(c) shows a symmetrical version of the situation shown in FIG. 7(c) in which the interaction areas are increased to the maximum, as shown as 140.

FIG. 9 shows schematically a more detailed cross sectional view of the degree of interaction between the cloud and a main pulse in two different situations in another modification of the first embodiment. The plane of this view is the X-Y plane, so that the direction of optical axis O is into (or out of) the page. In this modification, the location of the cross-sectional area of the laser radiation is offset and varied from pulse to pulse, together with variation in timing of the laser pulse, so as to reduce variation in said intensity distribution relative to an optical axis of the lithographic apparatus as the conversion efficiency is varied.

FIG. 9(a) shows a cross sectional view of the fuel cloud position 100a and a laser beam path 83a at a nominal conversion efficiency. An offset dt is applied so that the laser pulse is timed to occur slightly before (or slightly after) the fuel cloud 69 is centered on the optical axis O. To avoid the asymmetry of the plasma location that was seen in FIG. 7(a), however, in this modification, the laser beam path 83 is also offset in the opposite direction to a position 83a. The offset of the fuel cloud is labeled dt and the offset of the laser beam is labeled dL. As a consequence of these two offsets in opposite directions, the interaction area 202 of the cloud and laser pulse remains at least approximately centered on the optical axis O.

The laser offset dL can be applied by moving or tilting the mirror or other optic 65 that delivers laser radiation to the plasma location 73. Such a laser offset dL could be applied in a fixed or slowly-varying manner, simply to reduce the asymmetry caused by the offset associated with the nominal conversion efficiency value. Alternatively, if the optic can be moved quickly enough, it could be applied as part of the pulse-to-pulse variation. FIG. 9(b) illustrates the further option to adjust both the cloud position and the laser beam position to reduce the conversion efficiency from pulse to pulse, while keeping the interaction area 200 accurately centered on the optical axis. Rather than adjusting only the timing of the laser pulse (adjustment δt), the position of the laser beam path 83 is also adjusted pulse-to-pulse (adjustment δL) to a new position 83b. Adjustments in the opposite direction (not show) can be applied, to increase the conversion efficiency above the nominal value.

FIG. 10 illustrates the difference between a scanning direction and a non-scanning direction, in a plane transverse to the optical axis and in the vicinity of the patterning device MA and the substrate W. A stripe or slit ST of patterned illumination traverses a target portion of the substrate in a scanning direction that is, by convention, the Y direction. Asymmetries and other variations of illumination in the scanning (Y) direction tend to be averaged out during the scanning motion. Along the non-scanning (X) direction, however, any asymmetry or other variation of EUV intensity distribution will lead to a systematic non-uniformity in the resulting image on the substrate. Although the illumination system IL is designed to greatly reduce such variations, it cannot eliminate them completely. For this reason, it is particularly useful to be able to minimize asymmetry in the X direction at the plasma location.

Different elements of the above embodiments and modifications can be combined to achieve a desired performance. It is also understood that the time of generating the droplet may also be controlled to have the similar effect of controlling the time of firing a main pulse. However, controlling the laser pulse timing is likely to be easier, at a pulse-to-pulse timescale.

FIG. 11 depicts schematically the operation of an embodiment of the invention. Here, a reduced interaction between the cloud and main pulse 83 is achieved by reducing the pre-pulse energy, and the pre-pulse energy is varied then to vary the conversion efficiency from pulse to pulse. The inventors have evidence that, even for a situation with a perfect match between laser beam and fuel cloud, the conversion efficiency varies with cloud size. As will be appreciated, the quality of interaction between the fuel material and the laser radiation can be influenced by many factors, even while the entire droplet is within the laser beam.

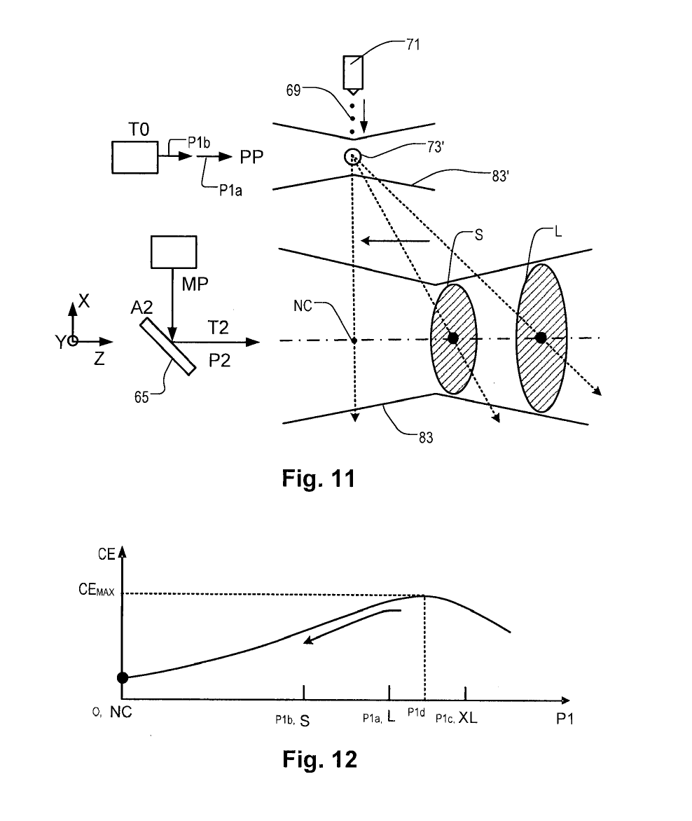

According to FIG. 11, when a pre-pulse is fired in beam path 83′ with energy P1a, the cloud is in a large expanded size L at the time T2 when the main pulse is fired. When the pre-pulse is fired with a lower energy P1b, the cloud is in a small expanded size S at the time T2. When no pre-pulse is fired, there is no cloud at time T2 and main pulse will fire towards an unexpanded droplet NC at time T2. If the pre-pulse energy can be controlled independently of the main pulse energy, a reduced size of the cloud can result in a lower CE when the energy of main pulse is constant, as shown in FIG. 12. In FIG. 12 the conversion efficiency CE is plotted as a function of pre-pulse energy P1 and at constant main-pulse energy P2. Along the horizontal axis both pre-pulse energies (P1=0, P1a, P1b, P1c) and corresponding degrees of size expansion (NC, S, L, XL) are indicated.

Therefore, according to an aspect of the invention aforementioned new EUV energy set point can also be translated into a change of pre-pulse energy. In case of a CO₂ laser where the pre-pulse emanating from the same cavity as the main pulse, this can be achieved by reducing the seed power, since the pre-pulse does not deplete the cavity. It is appreciated that it is not necessary to derive the pre-pulse and the main pulse from the same laser. The pre-pulse may also be delivered by a separate YAG laser, for example, in which case the pre-pulse power can be changed independently without complication.

In an embodiment according to an aspect of the invention, the arrangement of beam waists of the pre-pulse laser beam 83′ and the main-pulse laser beam 83 in aforementioned second embodiment and as shown in FIG. 11 is such that an undesired pulse-to-pulse variation of pre-pulse energy does not lead to a substantial change of conversion efficiency. This can be achieved by setting the nominal pre-pulse energy P1 at a value where the conversion efficiency is substantially constant, for example where the conversion efficiency has its maximum value CE_{MAX}. In FIG. 12 such a nominal pre-pulse energy is indicated by the value P1=P1d. Hence, in the configuration of the embodiment of FIG. 11, one may provide this way an intrinsic exposure dose stability in the presence of pulse-to-pulse variations of the pre-pulse energy P1. A characteristic of the arrangement of beam waists of the pre-pulse laser beam 83′ and the main-pulse laser beam 83 enabling the intrinsic exposure dose stability is that the pre pulse and main pulse laser beams are substantially parallel, and that the position of the beam waist of main pulse laser beam 83 is displaced along the direction of laser light propagation away from the beam waist of the pre-pulse laser beam 83′, the latter beam waist being substantially coincident with the position of the predetermined preconditioning position 73′.

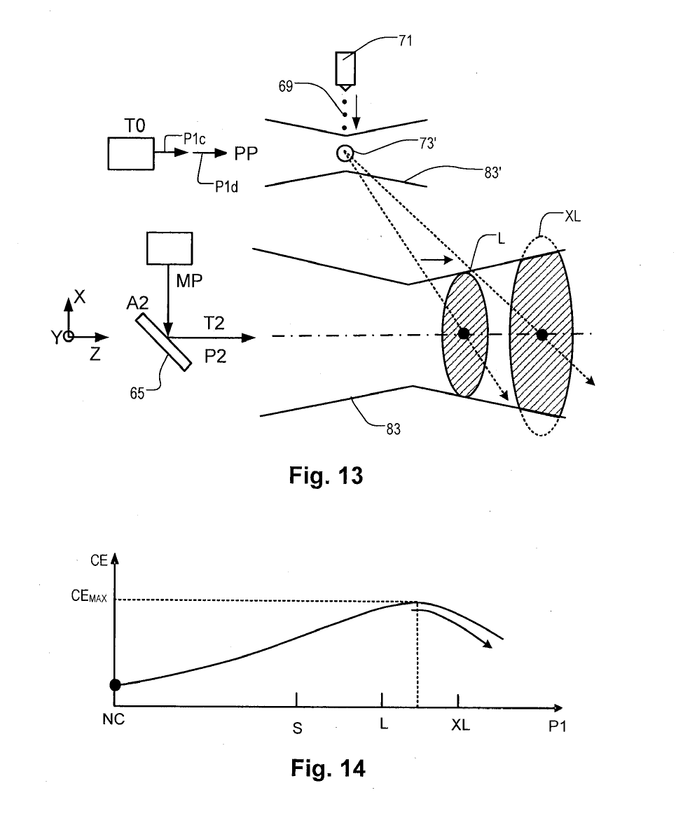

In FIGS. 11 and 12, the variation in CE is achieved while the entire fuel cloud is within the laser beam cross-section. FIG. 13 depicts an embodiment based on variation of pre-pulse energy, in which the proportion of the could which interacts with the laser beam is varied, not just the quality of the interaction. Referring to FIG. 13, when pre-pulse is fired with energy P1c, the cloud is in a fully expanded size L at the time T2 when the main pulse is fired. When pre-pulse is fired with a higher energy P1d, the cloud is in an overly expanded size XL at the time T2 so that its size is too large to effectively fit within the main beam path 83. When pre-pulse energy is controlled independently from main pulse energy, the increase of pre-pulse energy is not necessarily related to an increase of main pulse energy. If the pre-pulse energy is increased to an extent that the size of the expanded cloud is greater than the cross sectional area of the main laser pulse, the value of CE will decrease, as shown in FIG. 14.

As in the previous embodiment, the pre-pulse may be from a same laser system, or a separate laser. In the embodiments of FIGS. 11 to 14, the area of interaction where the plasma is generated remains centered on the optical axis. Therefore measures to correct asymmetry such as are described above may not be necessary. It is understood that the above described methods may be combined to achieve controlling exposure dose.

Apart from the above described methods, it may be possible to control exposure dose by defocusing the plasma with respect to the collector optic CO, so that only a portion of the radiation energy passes through the IF aperture and the rest of the radiation energy is incident the enclosure structure. However, defocusing the plasma is generally undesirable as the radiation energy incident on the enclosure structure brings heat and may damage the enclosure structure. Therefore, if it is to control exposure dose by defocusing the plasma, it is necessary to have a heat dissipation mechanism to absorb the heat in that instance.

In yet further embodiments, not illustrated, the conversion efficiency may be varied by displacing the droplets and/or the laser beam in the Y direction, instead of or in addition to the X direction. Displacement in the Y direction may be more difficult to implement, but may have the advantage that asymmetries can be introduced in the scanning direction, without such a negative impact on imaging performance.

In yet further embodiments, not illustrated, the conversion efficiency may be varied by moving the focus of the laser beam (beam waist) in the Z direction instead of or in addition to the X and/or Y directions. This may be for the pre-pulse and/or for the main pulse. The mechanism by which this affects the conversion efficiency may be by changing the quality of interaction between the laser radiation and the fuel material, and/or by reducing the proportion of the cloud that interacts with the beam. In all such embodiments the principle of designing the controller to set a nominal conversion efficiency below the maximum achievable can be employed, to allow easy adjustment up and down from the nominal value.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc.

Although specific reference may have been made above to the use of embodiments of the invention in the context of optical lithography, it will be appreciated that the invention may be used in other applications. Further embodiments may be provided by the following numbered clauses:

1. A method of controlling EUV exposure dose of a lithographic apparatus having an EUV radiation source of the type wherein pulses of EUV radiation are generated by excitation of expanded, heated portions of fuel material by corresponding pulses of an excitation laser radiation beam, the method comprising controlling, from pulse to pulse, a conversion efficiency with which said laser radiation is converted to said EUV radiation, wherein the fuel material is delivered firstly as a fuel droplet and then at a predetermined preconditioning position the fuel droplet is heated and expanded by a pre-pulse laser beam before encountering said excitation laser radiation beam at an excitation position, and wherein said controlling the conversion efficiency includes: arranging the pre-pulse laser beam such that a position of a beam waist of the pre-pulse laser beam substantially coincides with the predetermined preconditioning position; and arranging the excitation laser radiation beam such that a position of a beam waist of the excitation laser radiation beam is to be displaced along the direction of laser light propagation away from the excitation position.

2. The method according to clause 1, wherein controlling the conversion efficiency comprises setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

3. The method according to clause 2 or 3, wherein the step of controlling the conversion efficiency includes varying an energy of the pre-pulse relative to the excitation laser radiation pulse, thereby to vary the degree of expansion of the fuel material.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

What is claimed is:

1. A method of controlling EUV exposure dose of a lithographic apparatus having an EUV radiation source configured to generate pulses of EUV radiation by excitation of expanded, heated portions of fuel material by corresponding pulses of excitation laser radiation, the method comprising:
controlling, from pulse to pulse, a conversion efficiency with which said laser radiation is converted to said EUV radiation by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

2. The method of claim 1, wherein said controlling the conversion efficiency comprises controlling a proportion of the expanded fuel material that is excited by each laser pulse by varying a mutual cross-section between a cross-sectional area of the excitation laser radiation and a cross-sectional area of the expanded fuel material.

3. The method of claim 2, wherein the mutual cross-section is varied at least in part by advancing or retarding the timing of each pulse of excitation laser radiation while said fuel material traverses said laser radiation cross section, such that a greater or lesser proportion of said material is within the laser radiation cross section at the time of the pulse.

4. The method of claim 1, wherein the fuel material is delivered firstly as a fuel droplet and then heated and expanded by a pre-pulse of laser radiation before encountering said excitation laser radiation pulse, and wherein said controlling the conversion efficiency includes varying a timing of the pre-pulse delivery relative to the excitation laser radiation pulse to vary a location of the fuel material at the time of the excitation laser radiation pulse.

5. The method of claim 1, wherein the fuel material is delivered firstly as a fuel droplet and then heated and expanded by a pre-pulse of laser radiation before encountering said excitation laser radiation pulse, and wherein said controlling the conversion efficiency includes varying an energy of the pre-pulse relative to the excitation laser radiation pulse to vary the degree of expansion of the fuel material.

6. The method of claim 5, wherein a target pre-pulse energy is set to a level at which said fuel material is expanded to less than a size corresponding to a maximum achievable conversion efficiency but sufficient to achieve a target EUV exposure dose, such that both positive and negative dose corrections can be applied between pulses by varying the pre-pulse energy above and below said target pre-pulse energy.

7. The method of claim 5, wherein a target pre-pulse energy is set to a level at which said fuel material is expanded to greater than a size corresponding to a maximum achievable conversion efficiency but sufficient to achieve a target EUV exposure dose, such that both positive and negative dose corrections can be applied between pulses by varying the pre-pulse energy above and below said target pre-pulse energy.

8. The method of claim 1, wherein the variation of conversion efficiency also causes variation in an intensity distribution of the EUV radiation relative to an optical axis of the lithographic apparatus, and wherein the conversion efficiency is varied by different actions for different pulses, so as to maintain a more uniform intensity distribution, averaged over different pulses.

9. The method of claim 1, wherein the variation of conversion efficiency also causes variation in an intensity distribution of the EUV radiation relative to a cross-sectional area of the excitation laser radiation, and wherein the location of the cross-sectional area of the excitation laser radiation is varied from pulse to pulse as the conversion efficiency is varied, so as to reduce variation in said intensity distribution relative to an optical axis of the lithographic apparatus.

10. The method of claim 9, wherein varying of the location of the cross-sectional area of said laser radiation is performed using one or more movable optical elements.

11. The method of claim 1, wherein the fuel material is delivered firstly as a fuel droplet and then at a predetermined preconditioning position, the fuel droplet is heated and expanded by a pre-pulse of laser radiation before encountering said excitation laser radiation pulse, and wherein said controlling the conversion efficiency includes:
arranging pre-pulse and main pulse laser beams to be substantially parallel; and
arranging a position of a beam waist of the main pulse laser beam to be displaced along the direction of laser light propagation away from a beam waist of the pre-pulse laser beam, the beam waist of the pre-pulse laser beam being substantially coincident with the predetermined preconditioning position.

12. A device manufacturing method comprising:
controlling EUV exposure dose of a lithographic apparatus having an EUV radiation source configured to generate pulses of EUV radiation by excitation of expanded, heated portions of fuel material by corresponding pulses of excitation laser radiation by controlling, from pulse to pulse, a conversion efficiency with which said laser radiation is converted to said EUV radiation by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency;
patterning said EUV radiation to form a patterned beam of radiation; and
projecting the patterned beam of radiation onto a substrate.

13. A lithographic apparatus comprising:
a source of EUV radiation;
an illumination system configured to condition a radiation beam received from said EUV radiation source;
a support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate; and
a controller configured to control an exposure dose generated by said source of EUV radiation by controlling, from pulse to pulse, a conversion efficiency with which excitation laser radiation is converted to said EUV radiation by excitation of expanded, heated portions of fuel material by setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

14. A method of controlling EUV exposure dose of a lithographic apparatus having an EUV radiation source configured to generate pulses of EUV radiation by excitation of expanded, heated portions of fuel material by corresponding pulses of an excitation laser radiation beam, the method comprising:
controlling, from pulse to pulse, a conversion efficiency with which said laser radiation is converted to said EUV radiation, wherein the fuel material is delivered firstly as a fuel droplet and then at a predetermined preconditioning position the fuel droplet is heated and expanded by a pre-pulse laser beam before encountering said excitation laser radiation beam at an excitation position, and wherein said controlling the conversion efficiency includes
arranging the pre-pulse laser beam such that a position of a beam waist of the pre-pulse laser beam substantially coincides with the predetermined preconditioning position, and
arranging the excitation laser radiation beam such that a position of a beam waist of the excitation laser radiation beam is to be displaced along the direction of laser light propagation away from the excitation position.

15. The method according to claim 14, wherein said controlling the conversion efficiency comprises setting a target conversion efficiency that is lower than a maximum achievable conversion efficiency but sufficient to achieve a target EUV exposure dose, such that both positive and negative dose corrections can be applied between pulses by varying the conversion efficiency above and below said target conversion efficiency.

16. The method according to claim 14, wherein said controlling the conversion efficiency includes varying an energy of the pre-pulse laser beam relative to the excitation laser radiation beam pulse to vary the degree of expansion of the fuel material.
